(19) United States
(12) Patent Application Publication
(10) Pub. No.: US 2021/0203171 A1
(43) Pub. Date: Jul. 1, 2021

(54) POWER SUPPLY DEVICE AND POWER SUPPLY METHOD

(71) Applicant: ATEN INTERNATIONAL CO., LTD., New Taipei City (TW)

(72) Inventors: Chih-Wei HUANG, New Taipei City (TW); Chun-Ming LIU, New Taipei City (TW); Hsiang-Jui YU, New Taipei City (TW); Chun-Tang TSENG, New Taipei City (TW)

(21) Appl. No.: 17/033,614

(22) Filed: Sep. 25, 2020

(30) Foreign Application Priority Data
Dec. 30, 2019 (TW) 108148434

(51) Int. Cl. H02J 7/00; H02M 3/04; H02M 1/08; G01R 19/165

(52) U.S. Cl. CPC H02J 7/0019; H02J 7/0024; H02J 7/0048; G01R 19/16538; H02M 3/04; H02M 1/08; H02J 7/00714

(57) ABSTRACT

The present disclosure relates to a power supply device including a voltage conversion circuit, a switching circuit and a control circuit. The voltage conversion circuit is configured to generate a charging signal according to the power supply signal. The switching circuit is electrically connected to the voltage conversion circuit, and is configured to selectively conduct the voltage conversion circuit to a first device or a second device. The control circuit is configured to the switching circuit. When the voltage conversion circuit charges the first device and the charging signal corresponds to a first switching condition, the control circuit controls the switching circuit to disconnect to the voltage conversion circuit and the first device, then controls the switching circuit to connect to the voltage conversion circuit and the second device to charge the second device.

### CROSS-REFERENCE TO RELATED APPLICATION

This application claims priority to Taiwan Application Serial Number 108148434, filed Dec. 30, 2019, which is herein incorporated by reference in its entirety.

### BACKGROUND

### Technical Field

The present disclosure relates to a power supply device and a power supply method, in particular, the power supply device is electrically connected to multiple electronic devices for charging.

### Description of Related Art

With the improvement of the performance and the increase in battery power of various portable electronic devices, a power supply device that charges the electronic device has become more and more important. In order to supply a wider input voltage range in the current charging architecture, the power supply device needs to boost or bust the voltage of supply mains through a voltage conversion circuit to provide power to the back-end device or battery. However, for some power transmission protocols, the power generated by the voltage conversion circuit cannot be simultaneously supplied to multiple electronic devices. Therefore, the power supply device has many limitations and inconveniences in use.

### SUMMARY

One aspect of the present disclosure is a power supply device, comprising a voltage conversion circuit, a switching circuit and a control circuit. The voltage conversion circuit is configured to generate a charging signal according to a power supply signal. The switching circuit is electrically connected to the voltage conversion circuit, and is configured to selectively conduct the voltage conversion circuit and a first device or a second device, so that the voltage conversion circuit charges the first device or the second device. The control circuit is electrically connected to the switching circuit, wherein when the voltage conversion circuit charges the first device until the charging signal matches a first switching condition, the control circuit controls the switching circuit to disconnect the voltage conversion circuit and the first device, then controls the switching circuit to conduct the voltage conversion circuit and the second device to charge the second device.

Another aspect of the present disclosure is a power supply method, comprising: generating a charging signal according to a power supply signal through a voltage conversion circuit; controlling a switching circuit to conduct the voltage conversion circuit and a first transmission circuit so as to charge a first device according to the charging signal; determining whether the charging signal matches a first switching condition through a control circuit; and in a state that the charging signal matches a first switching condition, controlling a switching circuit to disconnect the voltage conversion circuit and the first device, and controlling the switching circuit to conduct the voltage conversion circuit and the second device, so that the voltage conversion circuit charges a second device.

Another aspect of the present disclosure is a power supply device, comprising a plurality of transmission circuits, a switching circuit and a control circuit. The plurality of transmission circuits are electrically connected to a plurality of electronic devices. The switching circuit is electrically connected to the plurality of transmission circuit, configured to receive a charging signal, and configured to selectively transmit a current signal to a first device of the plurality of electronic devices according to the charging signal through a first transmission circuit of the plurality of transmission circuit so as to charge the first device for a first time. The control circuit is electrically connected to the switching circuit, and configured to determine whether the charging signal matches a first switching condition. In a state that the control circuit determines that the charging signal matches the first switching condition, the control circuit is configured to control the switching circuit to conduct to a second device of the plurality of electronic devices so as to charge the second device for a first time.

It is to be understood that both the foregoing general description and the following detailed description are by examples, and are intended to provide further explanation of the disclosure as claimed.

### BRIEF DESCRIPTION OF THE DRAWINGS

The present disclosure can be more fully understood by reading the following detailed description of the embodiment, with reference made to the accompanying drawings as follows:

FIG. 1 is a schematic diagram of a power supply device in some embodiments of the present disclosure.

FIG. 2 is a schematic diagram of a power supply device and a Hub device in some embodiments of the present disclosure.

FIG. 3 is a schematic diagram of a power supply device and a Hub device in some embodiments of the present disclosure.

FIG. 4 is a schematic diagram of a power supply device in some embodiments of the present disclosure.

FIG. 5 is a flowchart illustrating a power supply method in some embodiments of the present disclosure

### DETAILED DESCRIPTION

The embodiments below are described in detail with the accompanying drawings, the embodiments are not provided to limit the scope of the present disclosure. Moreover, the operation of the described structure is not for limiting the order of implementation. Any device with equivalent functions that is produced from a structure formed by a recombination of elements is all covered by the scope of the present disclosure. Drawings are for the purpose of illustration only, and not plotted in accordance with the original size.

It will be understood that when an element is referred to as being “connected to” or “coupled to”, it can be directly connected or coupled to the other element or intervening elements may be present. In contrast, when an element to another element is referred to as being “directly connected” or “directly coupled,” there are no intervening elements present. As used herein, the term “and/or” includes an associated listed items or any and all combinations of more.

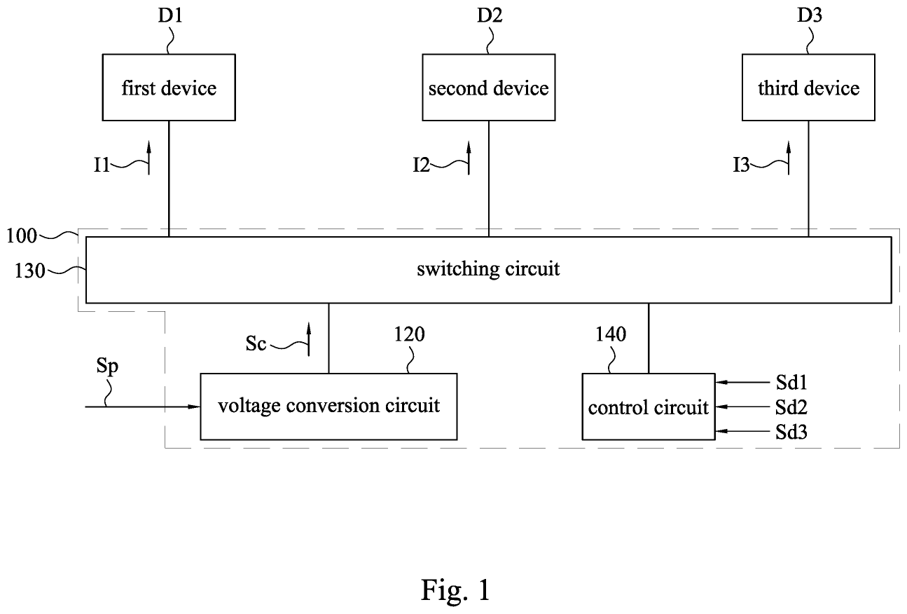

The present disclosure relates to a power supply device. FIG. 1 is a schematic diagram of a power supply device 100 in some embodiments of the present disclosure. In some embodiments, the power supply device 100 includes a voltage conversion circuit 120, a switching circuit 130 and a control circuit 140. The voltage conversion circuit 120 is configured to receive a power supply signal Sp, and configured to generate a charging signal Sc according to the power supply signal Sp. In some embodiments, the voltage conversion circuit 120 can be implemented by a Buck/Boost circuit, and is configured to convert the voltage of the power supply signal Sp to generate a charging signal Sc.

The switching circuit 130 is electrically connected to the voltage conversion circuit 120, and is configured to selectively conduct the voltage conversion circuit 120 and one of multiple electronic devices. As shown in FIG. 1, electronic devices include a first device D1, a second device D2 and a third device D3. Electronic devices can be smartphones, computers or various electronic devices. The switching circuit 130 conducts the voltage conversion circuit 120 and any one of the electronic devices, so that the voltage conversion circuit 120 may selectively charge the electronic device (i.e., the first device D1, the second device D2 or the third device D3). In some embodiments, the switching circuit 130 includes a power switch, and conducts the voltage conversion circuit 120 and the first device D1, the second device D2 or the third device D3 through multiple switching elements. The switching circuit 130 selectively conducts each of switching elements according to detection signals Sd1-Sd3. The operation of detection signals Sd1-Sd3 will be explained in the following paragraphs.

The control circuit 140 (e.g., Micro-Control Unit, MCU) is electrically connected to the switching circuit 130. When the voltage conversion circuit 120 charges the first device D1, and the charging signal Sc corresponds to a first switching condition, the control circuit 140 is configured to control the switching circuit 130 to disconnect the voltage conversion circuit 120 and the first device D1. Then, the control circuit 140 is further configured to control the switching circuit 130 to conduct the voltage conversion circuit 120 and the second device D2, so that the voltage conversion circuit 120 changes to charge the second device D2. In some embodiments, the switching circuit 130 disconnects the electrical connection between the voltage conversion circuit 120 and the first device D1 by turning off the internal switching element.

When the first device D1, the second device D2 and the third device D3 are already be charged, and the charging signal Sc provided to the devices D1-D3 from the power supply device 100 matches the first switching condition, the power supply device 100 charges the first device D1 again until the charging signal Sc corresponds to a second switching condition, then, change to charge the second device D2. The above method of charging sequentially and cyclically (or so called polling) allows all of the devices D1-D3 to obtain power.

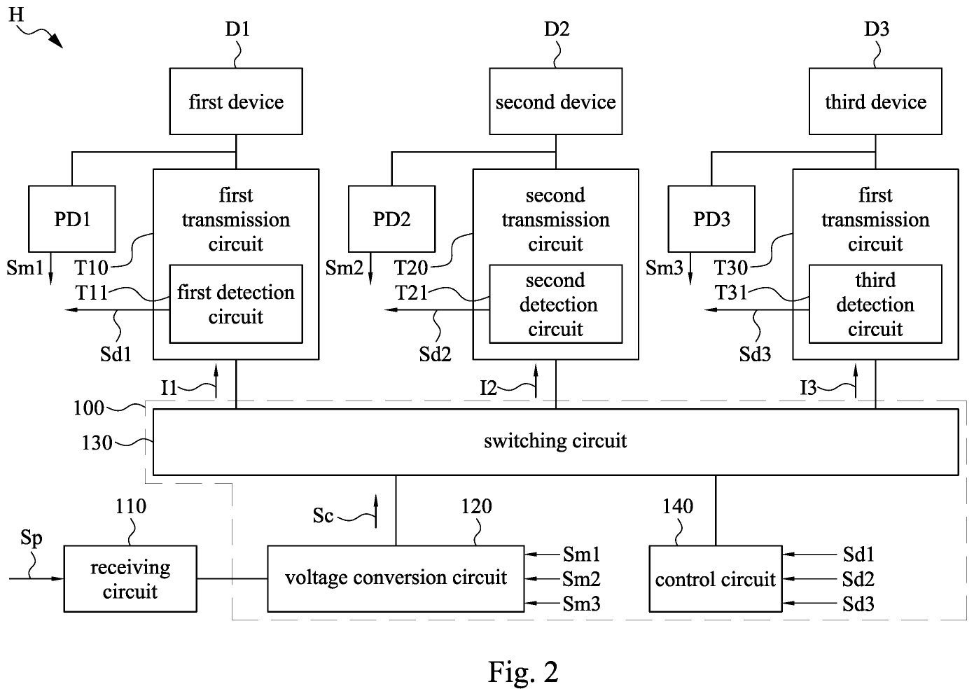

The power supply device is configured to provide power to the electronic device, the source of the power supply signal Sp can be supply mains. In some embodiments, the power supply device 100 is applicable to a hub device H or other electronic device with power supply function. FIG. 2 is another schematic diagram of a power supply device 100 in some embodiments of the present disclosure. The power supply device 100 is arranged in the hub device H. The hub device H indirectly receives the power supply signal Sp provided by the supply mains through the receiving circuit 110. The hub device H can have a power delivery function (e.g., Power Delivery) corresponding to the USB Type C format.

The present disclosure enables the voltage conversion circuit 120 to charge different electronic devices (e.g., the first device D1, the second device D2, the third device D3) in sequence by using the switching circuit 130. Furthermore, since the control circuit 140 may detect the charging signal Sc received by the switching circuit 130, the control circuit 140 determines the power state of the electronic devices (e.g., the first device D1, the second device D2, the third device D3) according to the value of the charging signal Sc (e.g., voltage or current). The control circuit 140 further sequentially changes to conduct different electronic devices to charge the first device D1, the second device D2 and the third device D3 according to the first switching condition.

As shown in FIG. 2, in some embodiments, the power supply device 100 is connected to the first device D1, the second device D2 and the third device D3 through multiple transmission circuits in the hub device H. The transmission circuits include a first transmission circuit T10, a second transmission circuit T20 and a third transmission circuit T30. Each of the transmission circuits T10-T30 has a transmission port (e.g., the connect port of Type C interface) to connect to the first device D1, the second device D2 and the third device D3.

Each of the transmission circuits T10-T30 includes a detection circuit T11-T31, which is configured to detect the power state of the first device D1, the second device D2 and the third device D3. The first detection circuit T11 is electrically connected to the switching circuit 130 and the control circuit 140. In the state that the switching circuit 130 conducts the voltage conversion circuit 120 and the first device D1, the first detection circuit T11 is configured to transmit a first detection signal Sd1 to the control circuit 140 according to the charging signal Sc (or a first current I1), so that the control circuit 140 determines whether the charging signal Sc matches the first switching condition or the second switching condition. In some embodiments, the first detection circuit T11 can be implemented by a galvanometer or a voltmeter.

The second detection signal T21 is electrically connected to the switching circuit 130 and the control circuit 140. In the state that the switching circuit 130 conducts the voltage conversion circuit 120 and the second device D2, the second detection circuit T21 is configured to transmit a second detection signal Sd2 to the control circuit 140 according to the charging signal Sc (or a second current I2). Similarly, the third detection circuit T31 is electrically connected to the switching circuit 130 and the control circuit 140, so as to transmit a third detection signal Sd3 to the control circuit 140 according to the charging signal Sc (or a third current 13).

The voltage conversion circuit 120 may adjust the charging signal Sc according to detection signals Sd1-Sd3. In some embodiments, when battery power of devices D1-D3 is charged to nearly full, the voltage conversion circuit 120 reduces the current value of the charging signal Sc. One of ordinary skill in the art is aware of various circuit structures and principles of transmission circuits T11-T31, thus a description in this regard is not further provided herein.

In some embodiments, the first switching condition and the second switching condition are stored in memory of the control circuit 140. The first switching condition includes a first current value (e.g., 2 amps). When the corresponding current of the charging signal Sc (e.g., the first current T1 provided to the first transmission circuit T10) has/reaches the first current value, the control circuit 140 controls the switching circuit 130 to disconnect the voltage conversion circuit 120 and the first device D1 (or the first transmission circuit T10), then controls the switching circuit 130 to conduct the voltage conversion circuit 120 and the second device D2 (or the second transmission circuit T20).

As mentioned above, when the voltage conversion circuit 120 charges the second device D2 until the corresponding current of the charging signal Sc has the first current value (e.g., the second current I2 provided to the second transmission circuit T20), the control circuit 140 controls the switching circuit 130 to conduct to other uncharged devices (e.g., the third device D3). When all devices are charged, the power supply device 100 will charge the first device D1 again. For example, the control circuit 140 controls the switching circuit 130 to disconnect the voltage conversion circuit 120 and the second device D2(or the second transmission circuit T20), so that the voltage conversion circuit 120 charges the first device D1 again until the charging signal Sc has a second current value of the second switching condition. The second current value is less than the first current value.

In the state that the voltage conversion circuit 120 charges the first device D1 again, when the corresponding current of the charging signal Sc has the second current value, the control circuit 140 controls the switching circuit 130 to disconnect the voltage conversion circuit 120 and the first device D1 (or the first transmission circuit T10), and to conduct the voltage conversion circuit 120 and the second device D2 (or the second transmission circuit T20), so that the voltage conversion circuit 120 charges the second device D2 again until the charging signal Sc has the second current value again.

For example, the voltage conversion circuit 120 first charges the first device D1 through the switching circuit 130 according to the charging signal Sc. At this time, the current of the charging signal Sc (e.g., first current I1) is 2 A. When the battery power of the first device D1 is charged to 80%, the voltage conversion circuit 120 reduces the current of the charging signal Sc to 1.5 A. If the first current value of the first switching condition is “1.5 A”, the control circuit 140 disconnects the switching circuit 130 and the first device D1 at this time, and controls the switching circuit 130 to conduct to the second device D2, so as to charge the second device D2.

Similarly, when the battery power of the second device D2 is charged to 80%, the control circuit 140 will control the switching circuit to conduct to the third device D3 in the same way, so as to charge the third device D3.

When the power supply device 100 sequentially charges the first device D1, the second device D2 and the third device D3, so that all of the battery power in the first device D1, the second device D2 and the third device D3 are charged to 80%, the voltage conversion circuit 120 charges the first device D1 again through the switching circuit 130 according to the charging signal Sc. When the battery power of the first device D1 is charged to 90%, the voltage conversion circuit 120 reduces the current of the charging signal Sc from 1.5 A to 0.5 A. At this time, if the second switching condition set in the control circuit 140 includes a second current value, and the second current value is “0.5 A”, the control circuit 140 controls the switching circuit 130 to disconnect the first device D1, and controls the switching circuit 130 to conduct the second device D2, so as to charge the second device D2.

Similarly, the power supply device 100 charges the second device D2 and the third device D3 in sequence until the battery power in the first device D1, the second device D2 and the third device D3 is charged to 90%. By using the above method of charging sequentially and cyclically, all of the batteries in devices D1-D3 could be fully charged.

In some other embodiments, the control circuit 140 further determines whether to adjust the switching circuit 130 by determining whether the charging signal Sc maintains at a stable value. The first switching condition includes a set time (e.g., 3 seconds) and a set current range (e.g., 1.75-2.25 A). When the power supply device 100 charges one of the devices D1-D3, the control circuit 140 determines whether the corresponding current of the charging signal Sc is maintained in the set current range within the set time. If the corresponding current of the charging signal Sc exceeds the set current range (e.g., 1.5 A), it means that the currently charged device has completed the current charging stage, so the control circuit 140 will control the switching circuit 130 to conduct another electronic device.

As shown in FIG. 2, in some embodiments, the hub device H further includes multiple power deliveries PD1-PD3, which are configured to detect the power state of devices D1-D3. Each of the power deliveries PD1-PD3 is electrically connected to the voltage conversion circuit 120 and the control circuit 140 through the Inter-Integrated Circuit Bus. For example, when the battery power in the first device D1 gradually decreases, the required charging current will increase, at this time the first power delivery PD1 will determine that the charging current required by the first device D1 (i.e., the first current I1) is higher than a predetermined value, and transmits a first adjustment signal Sm1 to the voltage conversion circuit 120, so that the voltage conversion circuit 120 adjusts the charging signal Sc to the current voltage value that the first device D1 can withstand, and charges the first device Dl. Similarly, the second power delivery PD2, and the third power delivery PD3 transmit the second adjustment signal Sm2 and the third adjustment signal Sm3 to the voltage conversion circuit 120 when the charging current required by the second device D2 and the third device D3 increases to a predetermined value.

The voltage conversion circuit 120, the control circuit 140 and the power deliveries PD1-PD3 can be implemented by a central processing unit, System on Chip (SoC), application processor, special function processing chip or controller. For example, the voltage conversion circuit 120 is a voltage conversion chip, the control circuit 140 is a microcontroller unit, and power deliveries PD1-PD3 can be a charge control chip.

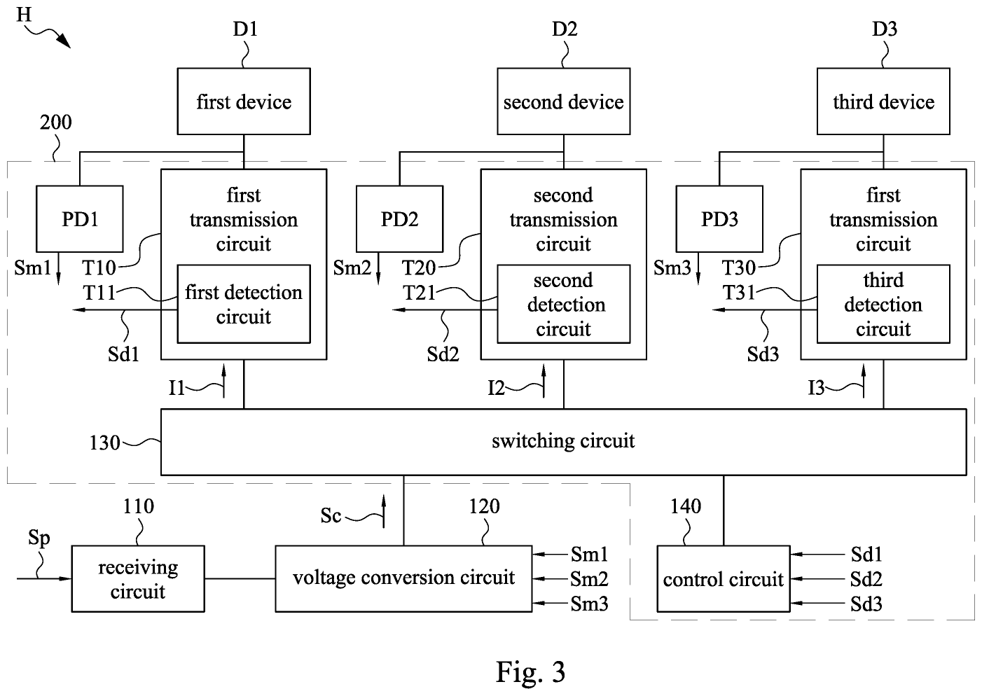

In addition to the embodiments shown in FIG. 1 and FIG. 2, in some other embodiments, the transmission circuits T10-T30 can also be directly installed in the power supply device 100. FIG. 3 is for illustrating another embodiment of the power supply device 200. In FIG. 3, the similar components associated with the embodiment of FIG. 1 are labeled with the same numerals for ease of understanding. The specific principle of the similar component has been explained in detail in the previous paragraphs, and unless it has a cooperative relationship with the components of FIG. 3, it is not repeated here.

In this embodiment, the power supply device 200 may be implemented in the hub device H, and includes multiple transmission circuits (e.g., the first transmission circuit T10, the second transmission circuit T20 and the third transmission circuit T30), the switching circuit 130 and the control circuit 140. The transmission circuits T10-T30 are respectively electrically connected to the electronic devices (e.g., the first device D1, the second device D2, the third device D3). The switching circuit 130 is configured to receive the charging signal Sc. The switching circuit 130 selectively transmits the corresponding current signal to a single one device of the electronic devices D1-D3 (e.g., the first device D1) through a single transmission circuit of transmission circuits T10-T30 (e.g., the first transmission circuit T10) according to the charging signal Sc, so as to charge the single device. In other words, the switching circuit 130 conducts to a single device (e.g., the first device D1, the second device D2 or the third device D3) at one time. In some embodiments, the switching circuit 130 is electrically connected to the voltage conversion circuit 120 to receive the charging signal Sc.

The control circuit 140 is electrically connected to the switching circuit 130 to determine whether the charging signal Sc matches the first switching condition. When the control circuit 140 determines the charging signal Sc matches the first switching condition, the control circuit 140 is configured to control the switching circuit 130 to conduct another one of electronic devices (e.g., the second device D2) through the second transmission circuit T20, so as to charge the other electronic device for the first time.

Similar to the embodiment shown in FIG. 1, in this embodiment, the first switching condition includes the first current value. When the single electronic device (e.g., the first device D1) is charged by the power supply device 200 first time, once the current signal reaches the first current value, the control circuit 140 controls the switching circuit 130 to conduct to another electronic device (e.g., the second device D2) to charge the another the electronic device for the first time.

In some embodiments, the control circuit 140 is further configured to control the switching circuit 130 to conduct the single electronic device (e.g., the first device D1) again, so as to charge the single electronic device until the current signal reaches a second current value which is less than the first current value. When the current signal reaches the second current value, the control circuit 140 is further configured to control the switching circuit 130 to conduct to another electronic device (e.g., the second device D2) to charge another electronic device second time until the current signal reaches the second current value. In some embodiments, only after all devices D1-D3 being charged first time, the power supply device 200 charges the first device D1 for the second time.

Similar to the embodiment shown in FIG. 1, in this embodiment, the power supply device 200 determines whether the current signal is maintained in the set current range within the set time according to the set time and the set current range of the first switching condition.

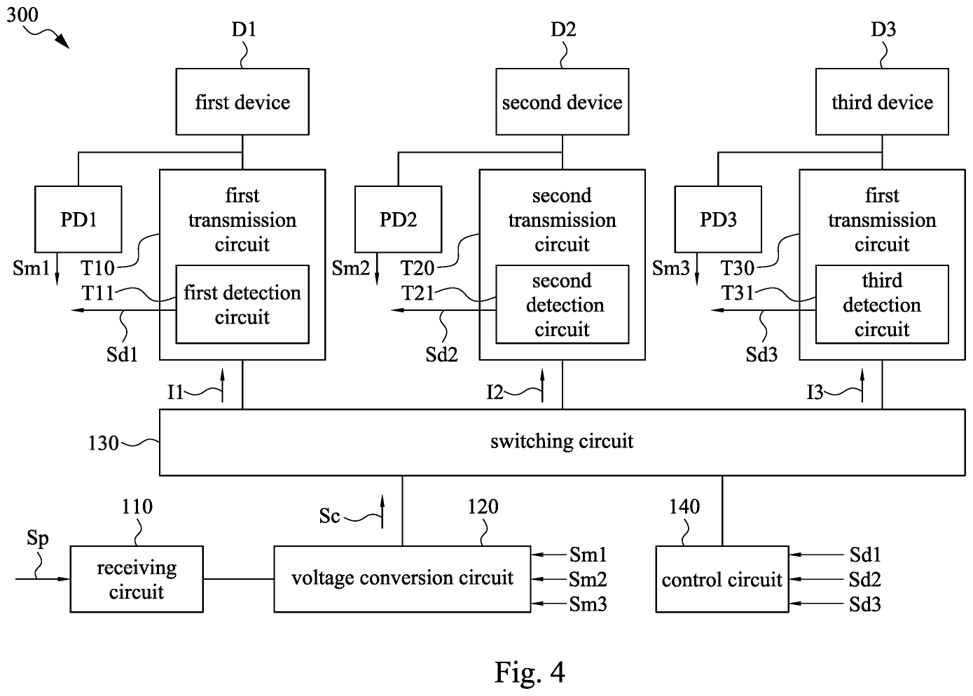

FIG. 4 is for illustrating another embodiment of the power supply device 300. In FIG. 4, the similar components associated with the embodiment of FIG. 1 are labeled with the same numerals for ease of understanding. The specific principle of the similar component has been explained in detail in the previous paragraphs, and unless it has a cooperative relationship with the components of FIG. 4, it is not repeated here.

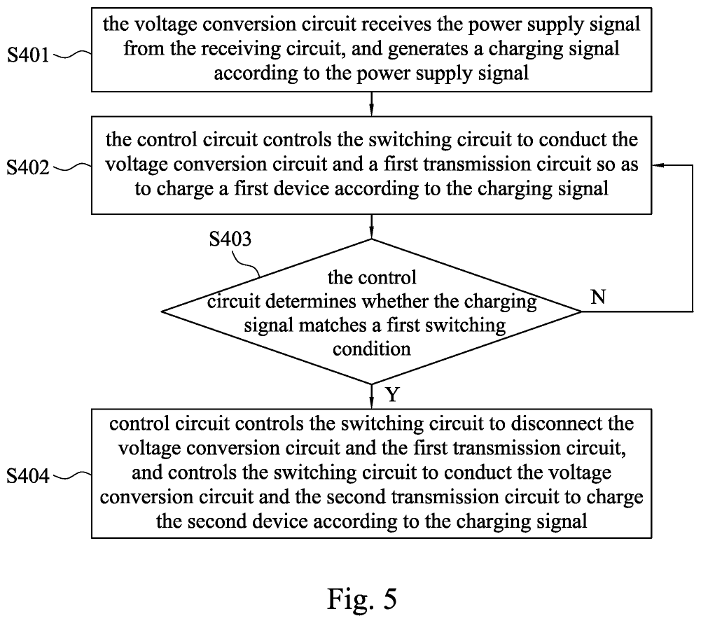

FIG. 5 is a flowchart illustrating a power supply method in some embodiments of the present disclosure. Referring to FIG. 4 and FIG. 5, in some embodiments, the power supply device 300 may be implemented in or implemented by a HUB device including multiple circuit elements as shown in FIG. 4. The power supply method includes steps S401-S404. In step S401, the voltage conversion circuit 120 receives the power supply signal Sp from the receiving circuit 110, and generates the charging signal Sc according to the power supply signal Sp. In some embodiments, the receiving circuit 110 connects to the supply mains to receive power.

In step S402, the control circuit 140 controls the switching circuit 130 to conduct the voltage conversion circuit 120 and the first transmission circuit T10 to charge the first device D1 according to the charging signal Sc. In some embodiments, the switching circuit 130 includes multiple switching elements, the switching circuit 130 turns on the switching element corresponding to the first transmission circuit T10, and turns off the switching element corresponding to the second transmission circuit T20 and the third transmission circuit T30.

In step S403, the control circuit 140 determines whether the charging signal Sc matches the first switching condition. As mentioned above, the first switching condition includes the first current value, or includes the set time and the set current range.

In step S404, in the state that the control circuit 140 determines the charging signal Sc matches the first switching condition, the control circuit 140 controls the switching circuit 130 to disconnect the voltage conversion circuit 120 and the first transmission circuit T1, and to conduct the voltage conversion circuit 120 and the second transmission circuit T2, so as to charge the second device D2 according to the charging signal Sc. In some embodiments, the control circuit 140 turns off the switching element corresponding to the first transmission circuit T10, and turns on the switching element corresponding to the second transmission circuit T20.

Similarly, in the embodiment shown in FIG. 4, the control circuit 140 stores the first switching condition and the second switching condition. The switching condition can be a fixed current threshold value, and can also include the set time and the set current range.

The execution order of the steps in the previous flowchart is merely an example, rather than a restriction to practical implementations.

It will be apparent to those skilled in the art that various modifications and variations can be made to the structure of the present disclosure without departing from the scope or spirit of the present disclosure. In view of the foregoing, it is intended that the present disclosure cover modifications and variations of this present disclosure provided they fall within the scope of the following claims.

What is claimed is:

1. A power supply device, comprising:
a voltage conversion circuit configured to generate a charging signal according to a power supply signal;
a switching circuit electrically connected to the voltage conversion circuit, and configured to selectively conduct the voltage conversion circuit and a first device or a second device, so that the voltage conversion circuit charges the first device or the second device; and
a control circuit electrically connected to the switching circuit, wherein when the voltage conversion circuit charges the first device until the charging signal matches a first switching condition, the control circuit controls the switching circuit to disconnect the voltage conversion circuit and the first device, then controls the switching circuit to conduct the voltage conversion circuit and the second device to charge the second device.

2. The power supply device of claim 1, wherein the first switching condition comprises a first current value, when a corresponding current of the charging signal has the first current value, the control circuit is configured to control the switching circuit to disconnect the voltage conversion circuit and the first device, then is configured to control the switching circuit to conduct the voltage conversion circuit and the second device.

3. The power supply device of claim 2, wherein when the voltage conversion circuit charges the second device until the corresponding current of the charging signal has the first current value, the control circuit is configured to control the switching circuit to conduct the voltage conversion circuit and the first device, and is configured to disconnect the voltage conversion circuit and the second device, so that the voltage conversion circuit charges the first device again until the corresponding current of the charging signal has a second current value, and the second current value is less than the first current value.

4. The power supply device of claim 3, wherein in a state that the voltage conversion circuit charges the first device, when the corresponding current of the charging signal has the second current value, the control circuit is configured to control the switching circuit to disconnect the voltage conversion circuit and the first device, and is configured to conduct the voltage conversion circuit and the second device, so that the voltage conversion circuit charges the second device again until the corresponding current of the charging signal has the second current value.

5. The power supply device of claim 1, wherein the first switching condition comprises a set time and a set current range, the control circuit is further configured to determine whether a corresponding current of the charging signal is maintained in the set current range within the set time.

6. The power supply device of claim 1, further comprising:
a first detection circuit electrically connected to the switching circuit and the control circuit, wherein in a state that the switching circuit conducts the voltage conversion circuit and the first device, the first detection circuit is configured to transmit a first detection signal to the control circuit according to the charging signal; and
a second detection circuit electrically connected to the switching circuit and the control circuit, wherein in a state that the switching circuit conducts the voltage conversion circuit and the second device, the second detection circuit is configured to transmit a second detection signal to the control circuit according to the charging signal.

7. A power supply method, comprising:
generating a charging signal according to a power supply signal by utilizing a voltage conversion circuit;
controlling a switching circuit to conduct the voltage conversion circuit and a first transmission circuit so as to charge a first device according to the charging signal;
determining whether the charging signal matches a first switching condition by utilizing a control circuit; and
in a state that the charging signal matches a first switching condition, controlling a switching circuit to disconnect the voltage conversion circuit and the first device, and controlling the switching circuit to conduct the voltage conversion circuit and a second transmission circuit, so that the voltage conversion circuit charges a second device.

8. The power supply method of claim 7, wherein determining whether the charging signal matches the first switching condition further comprising:
determining whether a corresponding current of the charging signal has a first current value.

9. The power supply method of claim 8, further comprising:
in a state that charging the second device, determining whether the corresponding current of the charging signal has the first current value; and
in a state that the corresponding current of the charging signal has the first current value, conducting the voltage conversion circuit and the first device, and disconnecting the voltage conversion circuit and the second transmission circuit so as to charge the first device again until the corresponding current of the charging signal has a second current value, and the second current value is less than the first current value.

10. The power supply method of claim 9, further comprising:
in a state that charging the first device, when the corresponding current of the charging signal has the second current value, disconnecting the voltage conversion circuit and the first device, and conducting the voltage conversion circuit and the second transmission circuit so as to charge the second device until the corresponding current of the charging signal has the second current value.

11. The power supply method of claim 7, wherein determining whether the charging signal matches the first switching condition further comprising:
determining whether a corresponding current of the charging signal is maintained in a set current range within a set time.

12. A power supply device, comprising:
a plurality of transmission circuits electrically connected to a plurality of electronic devices;
a switching circuit electrically connected to the plurality of transmission circuits, configured to receive a charging signal, and configured to selectively transmit a current signal to a first device of the plurality of electronic devices according to the charging signal through a first transmission circuit of the plurality of transmission circuit so as to charge the first device for a first time; and
a control circuit electrically connected to the switching circuit, and configured to determine whether the charging signal matches a first switching condition, wherein in a state that the control circuit determines that the charging signal matches the first switching condition, the control circuit is configured to control the switching circuit to conduct to a second device of the plurality of electronic devices so as to charge the second device for a first time.

13. The power supply device of claim 12, wherein the first switching condition comprises a first current value, in a state that charging the first device for the first time, when the current signal has the first current value, the control circuit is configured to control the switching circuit to conduct to the second device of the plurality of electronic devices so as to charge the second device for the first time.

14. The power supply device of claim 13, wherein the control circuit is further configured to control the switching circuit to conduct to the first device of the plurality of electronic devices so as to charge the first device for a second time until the current signal has a second current value, and the second current value is less than the first current value.

15. The power supply device of claim 14, wherein in the state that charging the first device for the second time, when the current signal has the second current value, the control circuit is further configured to control the switching circuit to conduct to the second device so as to charge the second device for a second time until the current signal has the second current value.

16. The power supply device of claim 12, wherein the first switching condition comprises a set time and a set current range, the control circuit is further configured to determine whether the current signal is maintained in the set current range within the set time.
